(19) United States
(12) Patent Application Publication
(10) Pub. No.: US 2024/0194642 A1
(43) Pub. Date: Jun. 13, 2024

(54) SEMICONDUCTOR PACKAGE

(71) Applicant: SAMSUNG ELECTRONICS CO., LTD., SUWON-SI (KR)

(72) Inventors: Sungmock HA, Suwon-si (KR); Hyunggyun NOH, Suwon-si (KR); Gunhee BAE, Suwon-si (KR); Jinsoo BAE, Suwon-si (KR); Iljoo CHOI, Suwon-si (KR)

(21) Appl. No.: 18/523,314

(22) Filed: Nov. 29, 2023

(30) Foreign Application Priority Data
Dec. 7, 2022 (KR) 10-2022-0170052

(51) Int. Cl. H01L 25/065; H01L 23/00; H01L 23/31; H01L 23/498; H01L 23/522

(52) U.S. Cl. CPC H01L 25/0652; H01L 23/3107; H01L 23/49822; H01L 23/49838; H01L 23/5226; H01L 24/08; H01L 24/16; H01L 24/32; H01L 24/73; H01L 2224/08146; H01L 2224/08245; H01L 2224/16145; H01L 2224/16225; H01L 2224/32145; H01L 2224/73204; H01L 2924/181

(57) ABSTRACT

A semiconductor package includes a lower chip. A chip stacked structure is arranged on the lower chip. The chip stacked structure includes a plurality of upper chips. An underfill layer is disposed between the lower chip and the chip stacked structure and between the plurality of upper chips. A molding layer surrounds the underfill layer and the chip stacked structure. The lower chip has at least one lower trench positioned on an upper surface of the lower chip. At least one of the plurality of upper chips has at least one upper trench on an upper surface of the at least one of the plurality of upper chips.

### CROSS-REFERENCE TO RELATED APPLICATION

This application claims priority under 35 U.S.C. § 119 to Korean Patent Application No. 10-2022-0170052, filed on Dec. 7, 2022 in the Korean Intellectual Property Office, the disclosure of which is incorporated by reference in its entirety herein.

### 1. TECHNICAL FIELD

The present disclosure relates to a semiconductor package, and more particularly, to a semiconductor package including a plurality of chips, which are stacked.

### 2. DISCUSSION OF RELATED ART

Electronic components mounted on electronic products have become increasingly miniaturized and lightweight as the electronic industry has advanced. For example, semiconductor packages mounted on electronic components are being developed to process high-capacity data while having a relatively small volume. Therefore, a semiconductor package including a plurality of chips that are stacked on each other has been proposed.

### SUMMARY

Embodiments of the present disclosure provide a semiconductor package capable of strengthening an adhesion strength of a plurality of chips while relieving stress applied to the plurality of chips.

According to an embodiment of the present disclosure, a semiconductor package includes a lower chip. A chip stacked structure is arranged on the lower chip. The chip stacked structure includes a plurality of upper chips. An underfill layer is disposed between the lower chip and the chip stacked structure and between the plurality of upper chips. A molding layer surrounds the underfill layer and the chip stacked structure. The lower chip has at least one lower trench positioned on an upper surface of the lower chip. At least one of the plurality of upper chips has at least one upper trench on an upper surface of the at least one of the plurality of upper chips.

According to an embodiment of the present disclosure, a semiconductor package includes a lower chip. A chip stacked structure is arranged on the lower chip. The chip stacked structure comprises a plurality of upper chips. An underfill layer is disposed between the lower chip and the chip stacked structure and between the plurality of upper chips. A molding layer surrounds the underfill layer and the chip stacked structure. The lower chip has at least one lower trench positioned on an upper surface of the lower chip. A portion of the at least one lower trench overlaps the molding layer in a vertical direction, and a remaining portion of the at least one lower trench overlaps the underfill layer in the vertical direction. The portion of the at least one lower trench overlapping the molding layer in the vertical direction is filled with the molding layer, and the remaining portion of the at least one lower trench overlapping the underfill layer in the vertical direction is filled with the underfill layer.

According to an embodiment of the present disclosure, a semiconductor package includes a package substrate. A redistribution structure is arranged on the package substrate. A sub-semiconductor package is arranged on the redistribution structure. A semiconductor chip is arranged on the redistribution structure and spaced apart from the sub-semiconductor package in a horizontal direction. The sub-semiconductor package comprises a lower chip and a chip stacked structure arranged on the lower chip. The chip stacked structure comprises a plurality of upper chips. An underfill layer is disposed between the lower chip and the chip stacked structure and between the plurality of upper chips. A molding layer surrounds the underfill layer and the chip stacked structure. The lower chip has at least one lower trench positioned on an upper surface of the lower chip. At least one of the plurality of upper chips has at least one upper trench positioned on an upper surface of the at least one of the plurality of upper chips.

### BRIEF DESCRIPTION OF THE DRAWINGS

Embodiments of the inventive concept will be more clearly understood from the following detailed description taken in conjunction with the accompanying drawings in which:

FIG. 1A is a plan view illustrating a semiconductor package according to an embodiment;

FIG. 1B is a cross-sectional view of the semiconductor package taken along a line A-A′ of FIG. 1A according to an embodiment;

FIG. 1C is an enlarged cross-sectional view of a region EX of FIG. 1B according to an embodiment;

FIGS. 2A and 2B are enlarged cross-sectional views of a region corresponding to the region EX of FIG. 1B according to embodiments of the present disclosure;

FIG. 3A is a plan view illustrating a semiconductor package according to an embodiment;

FIG. 3B is a cross-sectional view of the semiconductor package taken along a line B-B′ of FIG. 3A according to an embodiment;

FIG. 3C is an enlarged cross-sectional view of a region EX of FIG. 3B according to an embodiment;

FIGS. 4A and 4B are plan views each illustrating a semiconductor package according to embodiments of the present disclosure;

FIG. 5A is a plan view illustrating a semiconductor package according to an embodiment;

FIG. 5B is a cross-sectional view of the semiconductor package taken along a line C-C′ of FIG. 5A according to an embodiment;

FIG. 5C is an enlarged cross-sectional of a region EX of FIG. 5B according to an embodiment;

FIG. 6 is a cross-sectional view illustrating a semiconductor package according to an embodiment; and

FIGS. 7A and 7B are cross-sectional views illustrating a method of manufacturing a semiconductor package according to embodiments of the present disclosure.

### DETAILED DESCRIPTION OF EMBODIMENTS

Hereinafter, embodiments of the present disclosure are described in detail with reference to the accompanying drawings. Like components are denoted by like reference numerals throughout the specification, and repeated descriptions thereof may be omitted for economy of description.

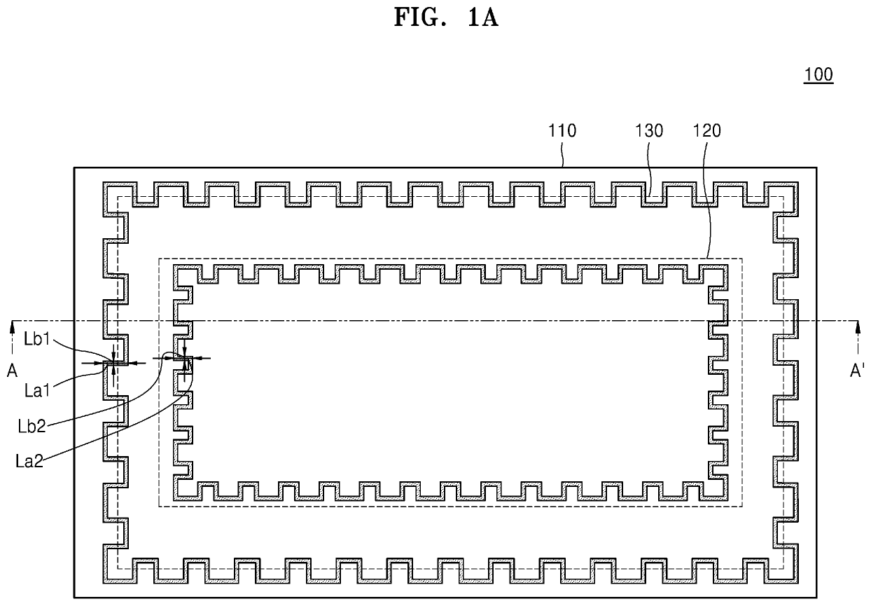

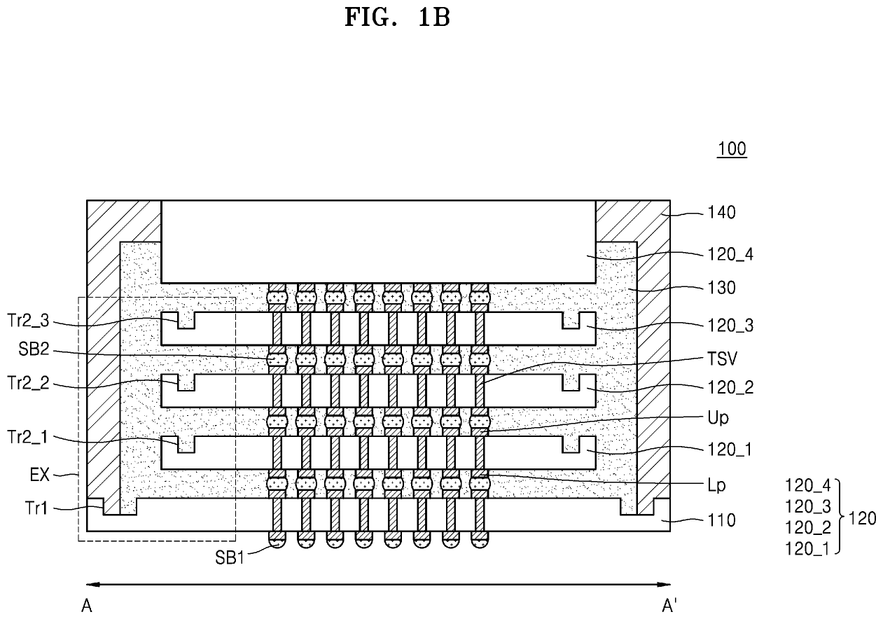

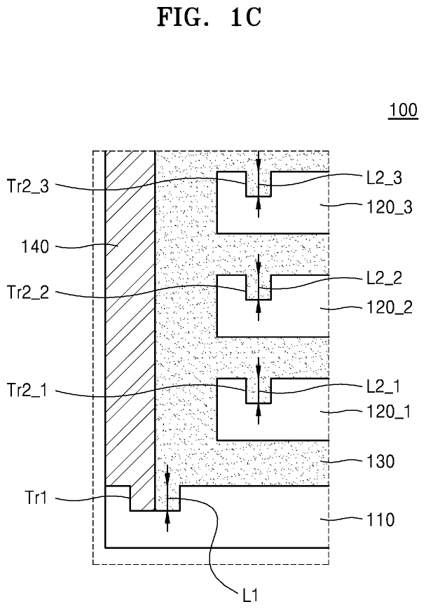

FIG. 1A is a plan view illustrating a semiconductor package 100 according to an embodiment. FIG. 1B is a cross-sectional view of the semiconductor package 100 taken along a line A-A′ of FIG. 1A. FIG. 1C is an enlarged cross-sectional view of a region EX of FIG. 1B.

Referring to FIGS. 1A to 1C, the semiconductor package 100 may include a lower chip 110, a chip stacked structure 120, an underfill layer 130, and a molding layer 140.

Hereinafter, unless otherwise specially defined, a direction parallel to an upper surface of the lower chip 110 is defined as a first horizontal direction, a direction perpendicular to the upper surface of the lower chip 110 is defined as a vertical direction, and a direction perpendicular to the first horizontal direction and the vertical direction is defined as a second horizontal direction.

In an embodiment, the lower chip 110 may be, for example, a buffer chip controlling a high bandwidth memory (HBM) dynamic random access memory (DRAM) chip. The lower chip 110 may include a plurality of through electrodes TSV, a plurality of lower pads Lp, and a plurality of upper pads Up.

In an embodiment, the lower chip 110 may include a group IV semiconductor such as silicon (Si) or germanium (Ge), a group IV-IV compound semiconductor such as silicon-germanium (SiGe) or silicon carbide (SiC), or group III-V compound semiconductor such as gallium arsenide (GaAs), indium arsenide (InAs), or indium phosphide (InP). However, embodiments of the present disclosure are not necessarily limited thereto. The lower chip 110 may include a conductive region, for example, a well doped with impurities or a structure doped with impurities. The lower chip 110 may have various device isolation structures, such as a shallow trench isolation (STI) structure.

The lower chip 110 may have an active surface and an inactive surface opposite to the active surface. Various types of a plurality of individual devices may be formed on the active surface. For example, in an embodiment the plurality of individual devices may include metal-oxide-semiconductor field effect transistors such as complementary metal-insulator-semiconductor transistors (CMOS) or the like, image sensors such as system large scale integration (LSI), CMOS imaging sensors (CIS) or the like, micro-electro-mechanical systems (MEMS), active elements, passive elements, or the like. However, embodiments of the present disclosure are not necessarily limited thereto.

The lower chip 110 may have a lower trench Tr1 on the upper surface thereof. In an embodiment, the lower trench Tr1 may be a single trench having a serpentine shape in a plan view. For example, the lower trench Tr1 may be a single trench positioned on the upper surface of the lower chip 110 and having a serpentine shape extending along an edge of the upper surface of the lower chip 110.

In an embodiment, the lower trench Tr1 may have a quadrangular cross section. For example, the lower trench Tr1 may have a quadrangular shape in a cross section perpendicular to the second horizontal direction.

In an embodiment, the lower trench Tr1 may overlap the underfill layer 130 and the molding layer 140 in the vertical direction. For example, a boundary line where the underfill layer 130 and the molding layer 140 come into direct contact with each other may be positioned between both side surfaces (e.g., lateral side surfaces) of the lower trench Tr1. Accordingly, based on the boundary line, an inner region of the lower trench Tr1 which is in direct contact with the underfill layer 130 in the vertical direction, may be filled with the underfill layer 130, and an outer region of the lower trench Tr1, which is in direct contact with the molding layer 140 in the vertical direction, may be filled with the molding layer 140.

In an embodiment, a first horizontal length La1 and a second horizontal length Lb1 of the lower trench Tr1 may each be in a range of about 1 μm to about 100 μm. However, embodiments of the present disclosure are not necessarily limited thereto. The first horizontal length La1 and the second horizontal length Lb1 may vary according to a horizontal area or vertical length of the lower chip 110.

In an embodiment, a vertical length L1 of the lower trench Tr1 may be in a range of about 1 μm to about 500 μm. However, embodiments of the present disclosure are not necessarily limited thereto. The vertical length L1 may vary according to the horizontal area or vertical length of the lower chip 110.

Each of the plurality of through electrodes TSV may pass through the lower chip 110 and extend in the vertical direction. The plurality of through electrodes TSV may be spaced apart from each other in the first horizontal direction. The plurality of through electrodes TSV may electrically connect the plurality of upper pads Up and the plurality of lower pads Lp to each other, respectively.

The plurality of lower pads Lp may be arranged on a lower surface of the lower chip 110. In an embodiment, the plurality of lower pads Lp may be arranged to respectively overlap the plurality of through electrodes TSV corresponding thereto in the vertical direction. The plurality of lower pads Lp may be respectively connected to (e.g., directly connected thereto in the vertical direction) the plurality of through electrodes TSV corresponding thereto.

The plurality of upper pads Up may be arranged on the upper surface of the lower chip 110. In an embodiment, the plurality of upper pads Up may be arranged to respectively overlap the plurality of through electrodes TSV corresponding thereto and the plurality of lower pads Lp corresponding thereto in the vertical direction. The plurality of upper pads Up may be respectively connected to (e.g., directly connected thereto in the vertical direction) the plurality of through electrodes TSV corresponding thereto.

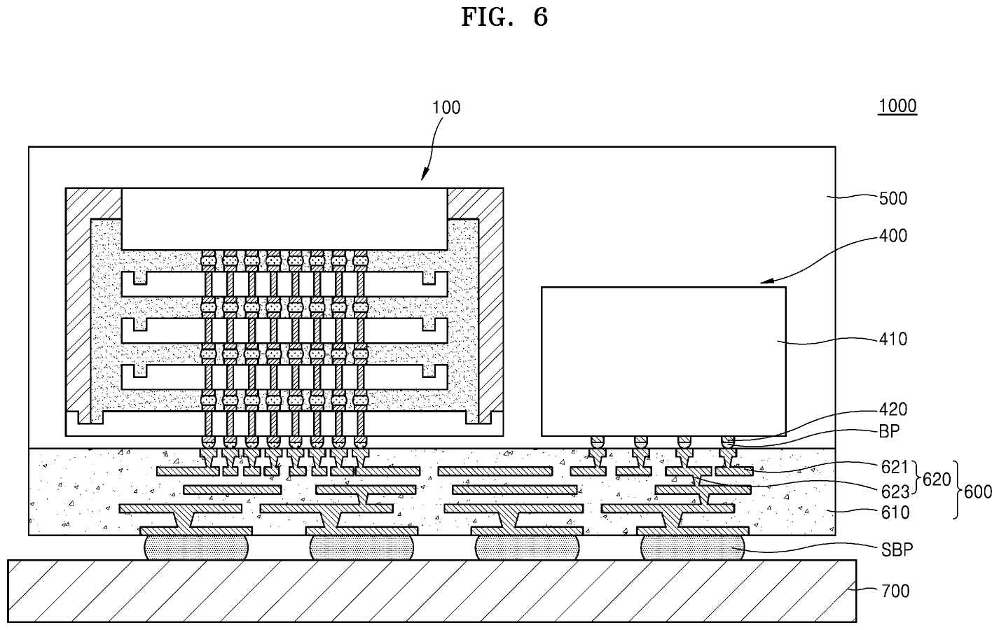

A plurality of first connection terminals SB1 may respectively be arranged on the plurality of lower pads Lp of the lower chip 110. In an embodiment, each of the plurality of first connection terminals SB1 may be, for example, a solder ball or a solder bump. Each of the plurality of first connection terminals SB1 may include a solder material. In an embodiment, the solder material may include, for example, tin (Sn), indium (In), bismuth (Bi), antimony (Sb), copper (Cu), silver (Ag), zinc (Zn), lead (Pb), and/or an alloy thereof. The lower chip 110 may be electrically connected to an external device (e.g., a redistribution structure 600 (refer to FIG. 6) through the plurality of first connection terminals SB1.

The chip stacked structure 120 may be arranged on the lower chip 110 (e.g., in the vertical direction). In an embodiment, the chip stacked structure 120 may include first to fourth upper chips 120_1, 120_2, 120_3, and 120_4, which are sequentially stacked (e.g., in the vertical direction). However, embodiments of the present disclosure are not necessarily limited thereto and the number of upper chips of the chip stacked structure 120 may vary. First horizontal lengths of the first to fourth upper chips 120_1, 120_2, 120_3, and 120_4 may be substantially the same or similar to each other. In an embodiment, a vertical length of the fourth upper chip 120_4, which is positioned at the uppermost end, may be greater than a vertical length of each of the first to third upper chips 120_1, 120_2, and 120_3.

In an embodiment, the first horizontal length of each of the first to fourth upper chips 120_1, 120_2, 120_3, and 120_4 may be less than the first horizontal length of the lower chip 110.

In an embodiment, each of the first to fourth upper chips 120_1, 120_2, 120_3, and 120_4 may be a volatile memory semiconductor chip, such as a DRAM or static random access memory (SRAM) chip, or a non-volatile memory chip, such as a phase-change random access memory (PRAM), magnetic random access memory (MRAM), ferroelectric random access memory (FeRAM), or resistive random access memory (ReRAM) chip. However, embodiments of the present disclosure are not necessarily limited thereto.

In an embodiment, each of the first to fourth upper chips 120_1, 120_2, 120_3, and 120_4 may be a DRAM chip, and the chip stacked structure 120 may configure HBM. However, embodiments of the present disclosure are not necessarily limited thereto.

Although FIG. 1B illustrates that the chip stacked structure 120 includes four upper chips, such as the first to fourth upper chips 120_1, 120_2, 120_3, and 120_4, embodiments of the present disclosure are not necessarily limited thereto. For example, in an embodiment, the chip stacked structure 120 may also include multiples of 4, for example, 8, 12, or 16 upper chips.

Each of the first to third upper chips 120_1, 120_2, and 120_3 may include the plurality of through electrodes TSV, the plurality of lower pads Lp, and the plurality of upper pads Up. The fourth upper chip 120_4 may include only the plurality of lower pads Lp and may not include the plurality of through electrodes TSV and the plurality of upper pads Up.

In an embodiment, each of the first to fourth upper chips 120_1, 120_2, 120_3, and 120_4 may include a semiconductor material substantially the same as or similar to that of the lower chip 110. Also, each of the first to fourth upper chips 120_1, 120_2, 120_3, and 120_4 may have a structure substantially the same as or similar to that of the lower chip 110.

The first to third upper chips 120_1, 120_2, and 120_3 may respectively have first to third upper trenches Tr2_1, Tr2_2, and Tr2_3 on upper surfaces thereof. For example, the first upper chip 120_1 may have the first upper trench Tr2_1 on the upper surface thereof, the second upper chip 120_2 may have the second upper trench Tr2_2 on the upper surface thereof, and the third upper chip 120_3 may have the third upper trench Tr2_3 on the upper surface thereof. In an embodiment, some of the first to third upper trenches Tr2_1, Tr2_2, and Tr2_3 may be omitted. For example, the second upper trench Tr2_2 and the third upper trench Tr2_3 may be omitted on the second upper chip 120_2 and third upper chip 120_3, respectively, and only the first upper trench Tr2_1 may be present on the upper surface of the first upper chip 120_1.

In an embodiment, each of the first to third upper trenches Tr2_1, Tr2_2, and Tr2_3 may have a serpentine shape in a plan view. For example, the first to third upper trenches Tr2_1, Tr2_2, and Tr2_3 may respectively be positioned on the upper surfaces of the first to third upper chips 120_1, 120_2, and 120_3, and may have a serpentine shape extending along edges of the upper surfaces of the first to third upper chips 120_1, 120_2, and 120_3, respectively.

In an embodiment, each of the first to third upper trenches Tr2_1, Tr2_2, and Tr2_3 may have a quadrangular cross section. For example, each of the first to third upper trenches Tr2_1, Tr2_2, and Tr2_3 may have a quadrangular shape in a cross section perpendicular to the second horizontal direction.

In an embodiment, each of the first to third upper trenches Tr2_1, Tr2_2, and Tr2_3 may overlap the underfill layer 130 in the vertical direction. Accordingly, the first to third upper trenches Tr2_1, Tr2_2, and Tr2_3 may be filled with the underfill layer 130.

In an embodiment, a first horizontal length La2 and a second horizontal length Lb2 of each of the first to third upper trenches Tr2_1, Tr2_2, and Tr2_3 may be in a range of about 1 μm to about 100 μm. For example, in an embodiment, within the range of about 1 μm to about 100 μm, the first horizontal length La2 and the second horizontal length Lb2 of each of the first to third upper trenches Tr2_1, Tr2_2, and Tr2_3 may be equal to each other or different from each other. For example, in an embodiment the first horizontal length La2 and the second horizontal length Lb2 of the first upper trench Tr2_1 may be different from the first horizontal length La2 and the second horizontal length Lb2 of the second upper trench Tr2_2, respectively. However, embodiments of the present disclosure are not necessarily limited thereto.

In an embodiment, vertical lengths L2_1, L2_2, and L2_3 of the first to third upper trenches Tr2_1, Tr2_2, and Tr2_3 may be in a range of about 1 μm to about 500 μm. For example, in an embodiment within the range of about 1 μm to about 500 μm, the vertical lengths L2_1, L2_2, and L2_3 of the first to third upper trenches Tr2_1, Tr2_2, and Tr2_3 may be equal to each other or different from each other. For example, in an embodiment the vertical length L2_1 of the first upper trench Tr2_1 may be different from the vertical length L2_2 of the second upper trench Tr2_2, and may be substantially equal to the vertical length L2_3 of the third upper trench Tr2_3. However, embodiments of the present disclosure are not necessarily limited thereto.

The plurality of through electrodes TSV may extend in the vertical direction through the first to third upper chips 120_1, 120_2, and 120_3. For example, the plurality of through electrodes TSV may extend in the vertical direction through an entirety of the thicknesses of each of the first to third upper chips 120_1, 120_2, and 120_3. The plurality of through electrodes TSV may be substantially the same as or similar to the plurality of through electrodes TSV included in the lower chip 110.

The plurality of lower pads Lp may be arranged on (e.g., directly thereon in the vertical direction) a lower surface of each of the first to fourth upper chips 120_1, 120_2, 120_3, and 120_4. The plurality of lower pads Lp may be substantially the same as or similar to the plurality of lower pads Lp included in the lower chip 110.

The plurality of upper pads Up may be arranged on (e.g., directly thereon in the vertical direction) the upper surface of each of the first to third upper chips 120_1, 120_2, and 120_3. The plurality of upper pads Up may be substantially the same as or similar to the plurality of upper pads Up included in the lower chip 110.

In an embodiment, a plurality of second connection terminals SB2 may be disposed between the first to fourth upper chips 120_1, 120_2, 120_3, and 120_4 and between the first upper chip 120_1 and the lower chip 110. For example, the plurality of second connection terminals SB2 disposed between the first fourth upper chips 120_1, 120_2, 120_3, and 120_4 and between the first upper chip 120_1 and the lower chip 110 may have an upper surface directly contacting a lower pad Lp and a lower surface directly contacting an upper pad Up. The plurality of second connection terminals SB2 may include materials substantially the same as or similar to those of the plurality of first connection terminals SB1. The first to fourth upper chips 120_1, 120_2, 120_3, and 120_4 and the lower chip 110 may be electrically connected to each other through the plurality of second connection terminals SB2.

The underfill layer 130 may be disposed between the first to fourth upper chips 120_1, 120_2, 120_3, and 120_4 and between the first upper chip 120_1 and the lower chip 110. The underfill layer 130 may surround the plurality of second connection terminals SB2, the plurality of lower pads Lp and the plurality of upper pads Up of the first to third upper chips 120_1, 120_2, and 120_3, the plurality of lower pads Lp of the fourth upper chip 1204, and the plurality of upper pads Up of the lower chip 110.

In an embodiment, the underfill layer 130 may extend in the first horizontal direction beyond lateral edges of the upper surface of each of the first to fourth upper chips 120_1, 120_2, 120_3, and 120_4. For example, the first horizontal length of the underfill layer 130 may be greater than the first horizontal length of each of the first to fourth upper chips 120_1, 120_2, 120_3, and 120_4. Accordingly, the underfill layer 130 may completely cover the upper surface of each of the first to third upper chips 120_1, 120_2, and 120_3 and completely fill the first to third upper trenches Tr2_1, Tr2_2, and Tr2_3.

In an embodiment, the underfill layer 130 may include a BPA epoxy resin, a BPF epoxy resin, an aliphatic epoxy resin, a cycloaliphatic epoxy resin, or the like. However, embodiments of the present disclosure are not necessarily limited thereto.

The molding layer 140 may be arranged on the lower chip 110 and may surround the chip stacked structure 120 and the underfill layer 130. In an embodiment as shown in FIG. 1B, an upper surface of the molding layer 140 may be coplanar with the upper surface of the fourth upper chip 120_4 of the chip stacked structure 120 (e.g., in the vertical direction). However, embodiments of the present disclosure are not necessarily limited thereto. For example, in an embodiment the upper surface of the molding layer 140 may also be positioned at a higher vertical level than the upper surface of the fourth upper chip 120_4 of the chip stacked structure 120. For example, the molding layer 140 may completely cover the upper surface of the fourth upper chip 120_4.

In an embodiment, the molding layer 140 may include an epoxy molding compound (EMC), an Ajinomoto Build-up Film (ABF), FR-4, bismaleimide triazine (BT), or the like. However, embodiments of the present disclosure are not necessarily limited thereto.

The semiconductor package 100 according to an embodiment may include the lower trench Tr1 positioned on the upper surface of the lower chip 110 and the first to third upper trenches Tr2_1, Tr2_2, and Tr2_3 respectively positioned on the upper surfaces of the first to third upper chips 120_1, 120_2, and 120_3. Due to the inclusion of the lower trench Tr1 and the first to third upper trenches Tr2_1, Tr2_2, and Tr2_3, thermo-mechanical stress applied to the upper surface of the lower chip 110 and the upper surface of each of the first to third upper chips 120_1, 120_2, and 120_3 may be reduced.

Also, the underfill layer 130 may fill the first to third upper trenches Tr2_1, Tr2_2, and Tr2_3, and the underfill layer 130 and the molding layer 140 may together fill the lower trench Tr1. Accordingly, an area in which each of the first to third upper chips 120_1, 120_2, and 120_3 and the underfill layer 130 directly contact each other and an area in which the lower chip 110, the underfill layer 130 and the molding layer 140 directly contact each other may be increased. Accordingly, an adhesion strength between each of the first to third upper chips 120_1, 120_2, and 120_3 and the underfill layer 130 and an adhesion strength between the lower chip 110, the underfill layer 130, and the molding layer 140 may be increased.

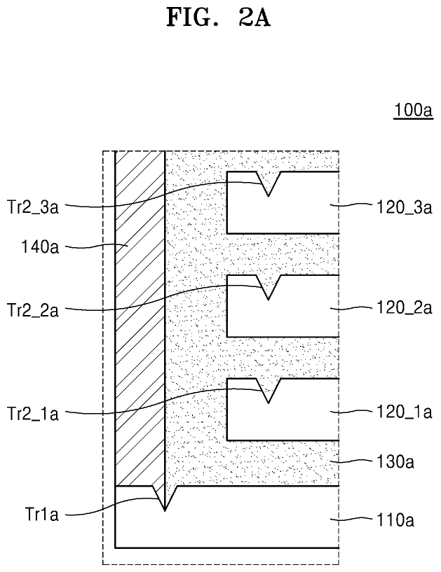

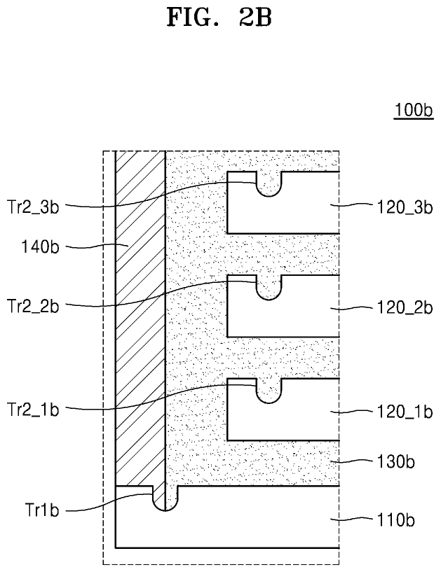

FIGS. 2A and 2B are enlarged cross-sectional views of a region corresponding to the region EX of FIG. 1B. In particular, FIG. 2A is an enlarged cross-sectional view of a semiconductor package 100a, and FIG. 2B is an enlarged cross-sectional view of a semiconductor package 100b. Each configuration of the semiconductor package 100a shown in FIG. 2A and each configuration of the semiconductor package 100b shown in FIG. 2B are similar to each configuration of the semiconductor package 100 described with reference to FIGS. 1A to 1C, and thus differences thereof are mainly described for economy of description.

Referring to FIG. 2A, in an embodiment the semiconductor package 100a may include a lower chip 110a having a lower trench Tr1a on an upper surface thereof and first to third upper chips 120_1a, 120_2a, and 120_3a respectively having first to third upper trenches Tr2_1a, Tr2_2a, and Tr2_3a on upper surfaces thereof.

In an embodiment, the lower trench Tr1a and the first to third upper trenches Tr2_1a, Tr2_2a, and Tr2_3a may each have a triangular cross section instead of the quadrangular cross section shown in an embodiment of FIG. 1C. For example, the lower trench Tr1a and the first to third upper trenches Tr2_1a, Tr2_2a, and Tr2_3a may each have a triangular shape in a cross section perpendicular to the second horizontal direction.

Referring to FIG. 2B, in an embodiment the semiconductor package 100b may include a lower chip 110b having a lower trench Tr1b on an upper surface thereof and first to third upper chips 120_1b, 120_2b, and 120_3b respectively having first to third upper trenches Tr2_1b, Tr2_2b, and Tr2_3b on upper surfaces thereof.

In an embodiment, the lower trench Tr1b and the first to third upper trenches Tr2_1b, Tr2_2b, and Tr2_3b may each have a U-shaped cross section instead of the quadrangular cross section shown in an embodiment of FIG. 1C. For example, the lower trench Tr1b and the first to third upper trenches Tr2_1b, Tr2_2b, and Tr2_3b may each have a U shape in a cross section perpendicular to the second horizontal direction.

Although the lower trench Tr1 and the first to third upper trenches Tr2_1, Tr2_2, and Tr2_3 shown in FIG. 1C, the lower trench Tr1a and the first to third upper trenches Tr2_1a, Tr2_2a, and Tr2_3a shown in FIG. 2A, and the lower trench Tr1b and the first to third upper trenches Tr2_1b, Tr2_2b, and Tr2_3b shown in FIG. 2B are all illustrated as having the same cross sections, embodiments of the present disclosure are not necessarily limited thereto. For example, in an embodiment the lower trench Tr1 may have a quadrangular cross section, the first upper trench Tr2_1 and the second upper trench Tr2_2 may each have a triangular cross section, and the third upper trench Tr2_3 may have a U-shaped cross section. In some other embodiments, the lower trench Tr1b and the first to third upper trenches Tr2_1b, Tr2_2b, and Tr2_3b may include the quadrangular cross section, the triangular cross section and/or the U-shaped cross section in various other arrangements.

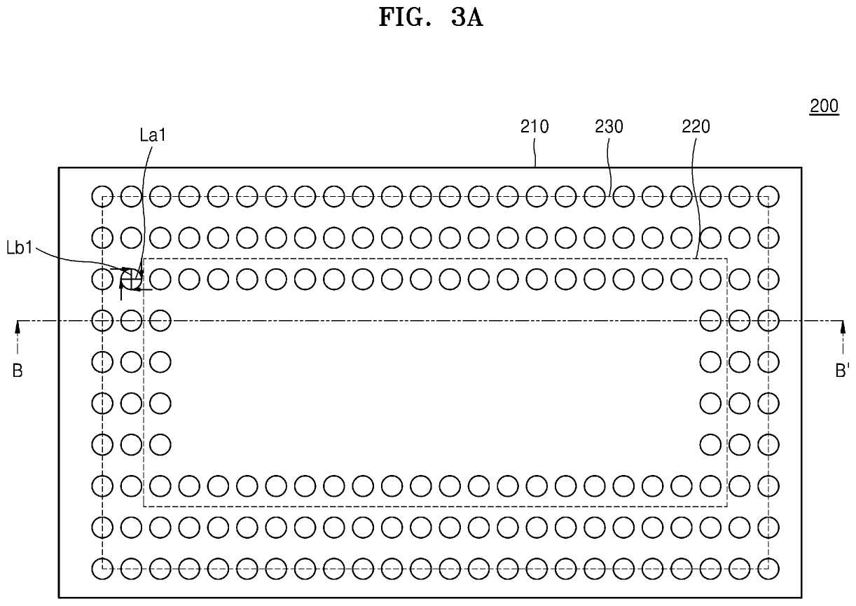

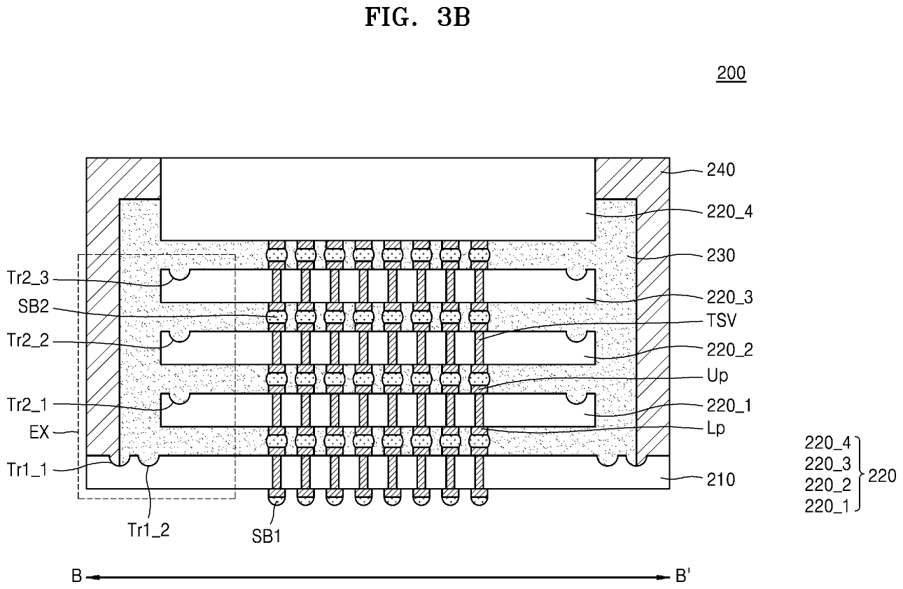

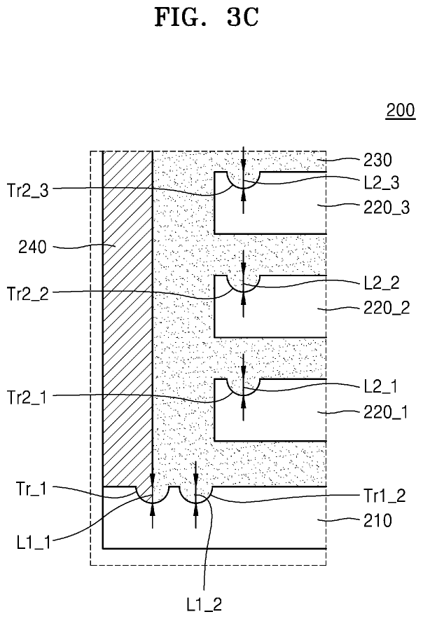

FIG. 3A is a plan view illustrating a semiconductor package 200 according to an embodiment. FIG. 3B is a cross-sectional view of the semiconductor package 200 taken along a line B-B′ of FIG. 3A. FIG. 3C is an enlarged cross-sectional view of a region EX of FIG. 3B.

Each configuration of the semiconductor package 200 shown in FIGS. 3A to 3C is similar to each configuration of the semiconductor package 100 described with reference to FIGS. 1A to 1C, and thus differences thereof are mainly described for economy of description.

Referring to FIGS. 3A to 3C, the semiconductor package 200 may include a lower chip 210, a chip stacked structure 220, an underfill layer 230, and a molding layer 240.

The lower chip 210 may include the plurality of through electrodes TSV, the plurality of lower pads Lp, and the plurality of upper pads Up.

The lower chip 210 may have a plurality of first lower trenches Tr1_1 and a plurality of second lower trenches Tr1_2 positioned on an upper surface thereof. In an embodiment, the plurality of first lower trenches Tr1_1 and the plurality of second lower trenches Tr1_2 may each have a circular shape in a plan view and a semi-circular shape in a cross section. In an embodiment, the plurality of first lower trenches Tr1_1 may be arranged on the upper surface of the lower chip 210 to be spaced apart from each other along an edge of the upper surface of the lower chip 210, and the plurality of second lower trenches Tr1_2 may respectively be arranged inside the plurality of first lower trenches Tr1_1 on the upper surface of the lower chip 210 to be spaced apart from each other and the plurality of first lower trenches Tr1_1 along the edge of the upper surface of the lower chip 210. For example, the plurality of first lower trenches Tr1_1 and the plurality of second lower trenches Tr1_2 may form a plurality of lower trenches that are arranged in two rows (e.g., extending along the first and second horizontal directions) along the edge of the upper surface of the lower chip in a plan view.

In an embodiment, the plurality of first lower trenches Tr1_1 may overlap the underfill layer 230 and the molding layer 240 in the vertical direction. For example, a boundary line where the underfill layer 230 and the molding layer 240 come into direct contact with each other may be positioned between both lateral side surfaces of the plurality of first lower trenches Tr1_1. Accordingly, based on the boundary line, an inner region of each of the plurality of first lower trenches Tr1_1, which is in direct contact with the underfill layer 230 in the vertical direction, may be filled with the underfill layer 230, and an outer region of each of the plurality of first lower trenches Tr1_1, which is in direct contact with the molding layer 240 in the vertical direction, may be filled with the molding layer 240.

In an embodiment, the plurality of second lower trenches Tr1_2 may each overlap the underfill layer 130 in the vertical direction. Accordingly, each of the plurality of second lower trenches Tr1_2 may be filled with the underfill layer 230.

In an embodiment, a first horizontal length and a second horizontal length of each of the plurality of first lower trenches Tr1_1 may be substantially equal to the first horizontal length La1 and the second horizontal length Lb1 of each of the plurality of second lower trenches Tr1_2. However, embodiments of the present disclosure are not necessarily limited thereto.

In an embodiment, the first horizontal length La1 and the second horizontal length Lb1 may each be in a range of about 1 μm to about 100 μm.

In an embodiment, a vertical length L1_1 of each of the plurality of first lower trenches Tr1_1 may be substantially equal to a vertical length L1_2 of each of the plurality of second lower trenches Tr1_2. However, embodiments of the present disclosure are not necessarily limited thereto.

In an embodiment, the vertical lengths L1_1 and L1_2 may each be in a range of about 1 μm to about 500 μm.

The plurality of first connection terminals SB1 may respectively be arranged on the plurality of lower pads Lp of the lower chip 210.

The chip stacked structure 220 may be arranged on the lower chip 210 (e.g., in the vertical direction). In an embodiment, the chip stacked structure 220 may include first to fourth upper chips 220_1, 220_2, 220_3, and 220_4, which are sequentially stacked (e.g., in the vertical direction). However, embodiments of the present disclosure are not necessarily limited thereto and the number of the upper chips of the chip stacked structure 220 may vary. Each of the first to third upper chips 220_1, 220_2, and 220_3 may include the plurality of through electrodes TSV, the plurality of lower pads Lp, and the plurality of upper pads Up. The fourth upper chip 220_4 may include only the plurality of lower pads Lp and may not include the plurality of through electrodes TSV and the plurality of upper pads Up.

The first to third upper chips 220_1, 220_2, and 220_3 may respectively have a plurality of first upper trenches to a plurality of third upper trenches Tr2_1, Tr2_2, and Tr2_3 positioned on upper surfaces thereof. For example, the first upper chip 220_1 may have the plurality of first upper trenches Tr2_1 positioned on the upper surface thereof, the second upper chip 220_2 may have the plurality of second upper trenches Tr2_2 positioned on the upper surface thereof, and the third upper chip 220_3 may have the plurality of third upper trenches Tr2_3 positioned on the upper surface thereof. In an embodiment, some of the first to third upper trenches Tr2_1, Tr2_2, and Tr2_3 may be omitted. For example, the second upper trench Tr2_2 and the third upper trench Tr2_3 may be omitted, and only the plurality of first upper trenches Tr2_1 may be present on the upper surface of the first upper chip 220_1.

In an embodiment, the plurality of first upper trenches to the plurality of third upper trenches Tr2_1, Tr2_2, and Tr2_3 may each have a circular shape in a plan view and a semi-circular shape in a cross section. In an embodiment, the plurality of first upper trenches to the plurality of third upper trenches Tr2_1, Tr2_2, and Tr2_3 may respectively be arranged on the upper surfaces of the first to third upper chips 220_1, 220_2, and 220_3 to be spaced apart from each other along edges of the upper surfaces of the first to third upper chips 220_1, 220_2, and 220_3. For example, the plurality of second upper trenches Tr2_2 may be arranged on the upper surface of the second upper chip 220_2 to be spaced apart from each other along the edge of the upper surface of the second upper chip 220_2.

In an embodiment, each of the plurality of first upper trenches to the plurality of third upper trenches Tr2_1, Tr2_2, and Tr2_3 may overlap the underfill layer 230 in the vertical direction. Accordingly, each of the plurality of first upper trenches to the plurality of third upper trenches Tr2_1, Tr2_2, and Tr2_3 may be filled with the underfill layer 230.

In an embodiment, a first horizontal length and a second horizontal length of each of the plurality of first upper trenches Tr2_1, a first horizontal length and a second horizontal length of each of the plurality of second upper trenches Tr2_2, and a first horizontal length and a second horizontal length of each of the plurality of third upper trenches Tr2_3 may be substantially equal to each other. However, embodiments of the present disclosure are not necessarily limited thereto.

In an embodiment, the first horizontal length and the second horizontal length of each of the plurality of first upper trenches to the plurality of third upper trenches Tr2_1, Tr2_2, and Tr2_3 may each be in a range of about 1 m to about 100 μm.

In an embodiment, a vertical length L2_1 of each of the plurality of first upper trenches Tr2_1, a vertical length L2_2 of each of the plurality of second upper trenches Tr2_2, and a vertical length L2_3 of each of the plurality of third upper trenches Tr2_3 may be substantially equal to each other. However, embodiments of the present disclosure are not necessarily limited thereto.

In an embodiment, the vertical lengths L2_1, L2_2, and L2_3 may each be in a range of about 1 μm to about 500 μm.

The plurality of second connection terminals SB2 may be disposed between the first to fourth upper chips 220_1, 220_2, 220_3, and 220_4 and between the first upper chip 220_1 and the lower chip 210. For example, the plurality of second connection terminals SB2 disposed between the first fourth upper chips 220_1, 220_2, 220_3, and 220_4 and between the first upper chip 220_1 and the lower chip 210 may have an upper surface directly contacting a lower pad Lp and a lower surface directly contacting an upper pad Up.

The underfill layer 230 may be disposed between the first to fourth upper chips 220_1, 220_2, 220_3, and 220_4 and between the first upper chip 2201 and the lower chip 210.

The molding layer 240 may be arranged on the lower chip 210 and may surround the chip stacked structure 220 and the underfill layer 230.

The semiconductor package 200 according to an embodiment may include the plurality of first lower trenches Tr1_1 and the plurality of second lower trenches Tr1_2 positioned on the upper surface of the lower chip 210 and the first to third upper trenches Tr2_1, Tr2_2, and Tr2_3 respectively positioned on the upper surfaces of the first to third upper chips 220_1, 220_2, and 220_3. Due to the plurality of first lower trenches Tr1_1, the plurality of second lower trenches Tr1_2, and the first to third upper trenches Tr2_1, Tr2_2, and Tr2_3, thermo-mechanical stress applied to the upper surface of the lower chip 210 and the upper surface of each of the first to third upper chips 220_1, 220_2, and 220_3 may be reduced.

Also, the underfill layer 230 may fill the plurality of second lower trenches Tr1_2 and the first to third upper trenches Tr2_1, Tr2_2, and Tr2_3, and the underfill layer 230 and the molding layer 240 may together fill the plurality of first lower trenches Tr1_1. Accordingly, an area in which each of the lower chip 210 and the first to third upper chips 220_1, 220_2, and 220_3 directly contact the underfill layer 230 and an area in which the lower chip 210, the underfill layer 230, and the molding layer 240 directly contact each other may be increased. Accordingly, an adhesion strength between each of the lower chip 210 and the first to third upper chips 220_1, 220_2, and 220_3 and the underfill layer 230 and an adhesion strength between the lower chip 210, the underfill layer 230, and the molding layer 240 may be increased.

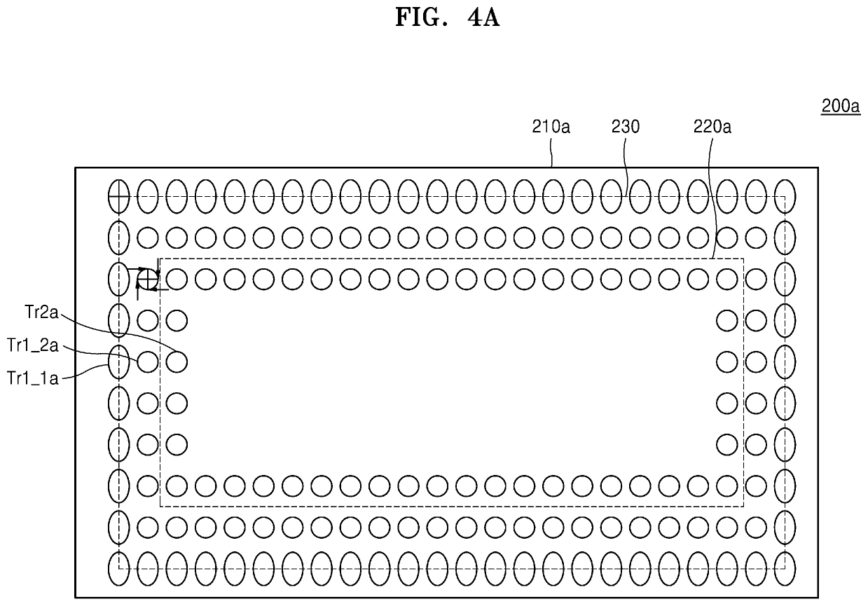

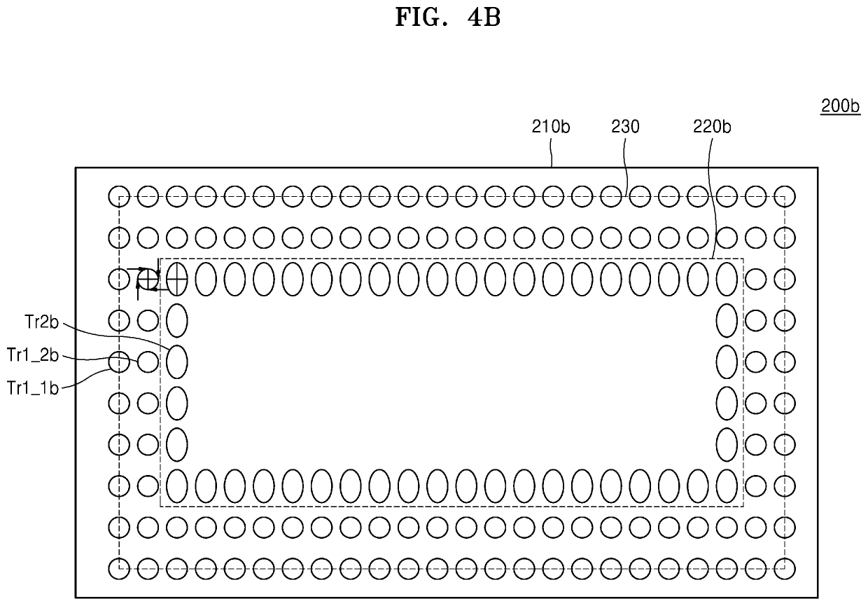

FIGS. 4A and 4B are plan views respectively illustrating semiconductor package 200a and 200b according to an embodiment. Each configuration of the semiconductor packages 200a and 200b shown in FIGS. 4A and 4B is similar to each configuration of the semiconductor package 200 described with reference to FIGS. 3A to 3C, and thus differences thereof are mainly described for economy of description.

Referring to FIG. 4A, the semiconductor package 200a may include a lower chip 210a having a plurality of first lower trenches Tr1_1a and a plurality of second lower trenches Tr1_2a positioned on an upper surface thereof and a chip stacked structure 220a having a plurality of upper trenches Tr2a positioned on an upper surface of each of stacked upper layers.

In an embodiment, the plurality of first lower trenches Tr1_1a may each have an elliptical shape in a plan view, and the plurality of second lower trenches Tr1_2a and the plurality of upper trenches Tr2a may each have a circular shape in a plan view.

Referring to FIG. 4B, the semiconductor package 200b may have a lower chip 210b having a plurality of first lower trenches Tr1_1b and a plurality of second lower trenches Tr1_2b and a chip stacked structure 220b having a plurality of upper trenches Tr2b positioned on an upper surface of each of stacked upper chips.

In an embodiment, the plurality of first lower trenches Tr1_1b and the plurality of second lower trenches Tr1_2b may each have a circular shape in a plan view, and the plurality of upper trenches Tr2b may each have an elliptical shape in a plan view.

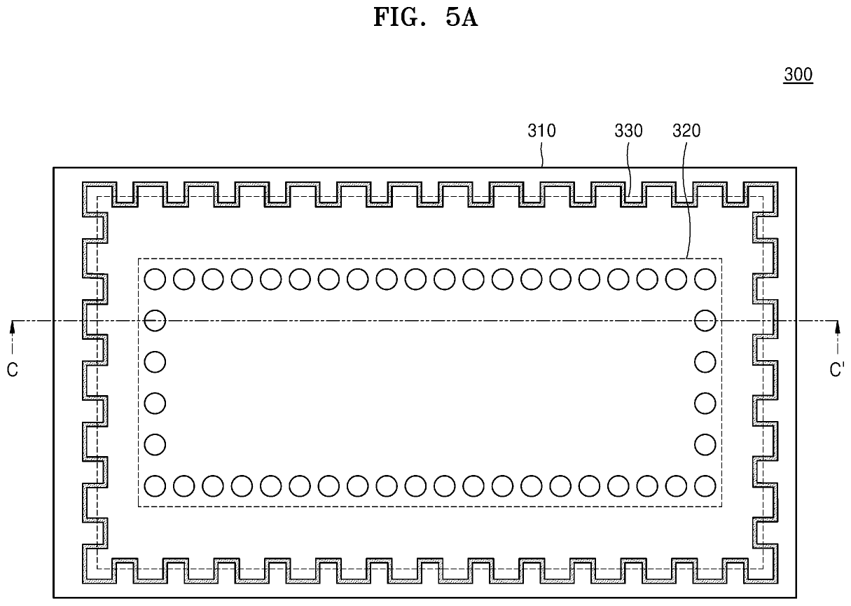

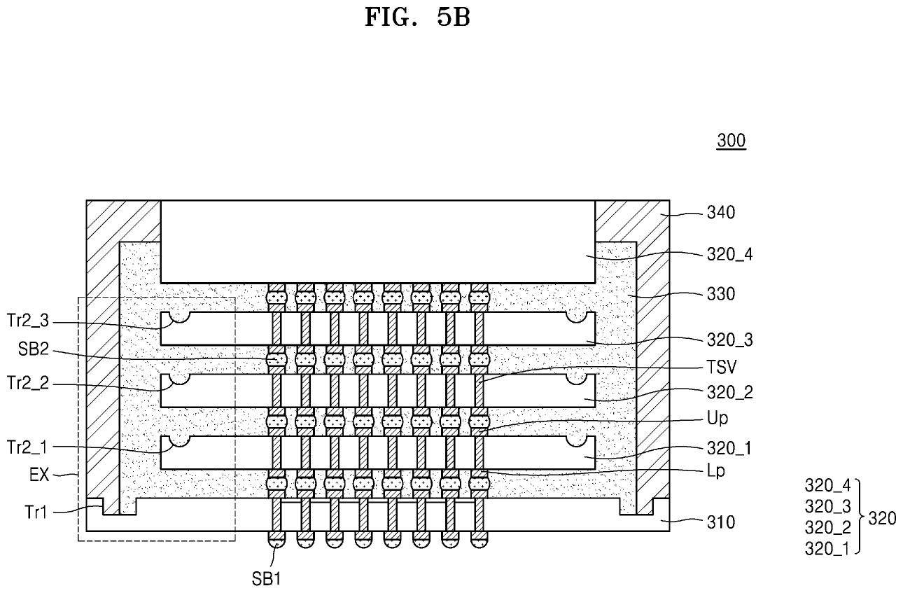

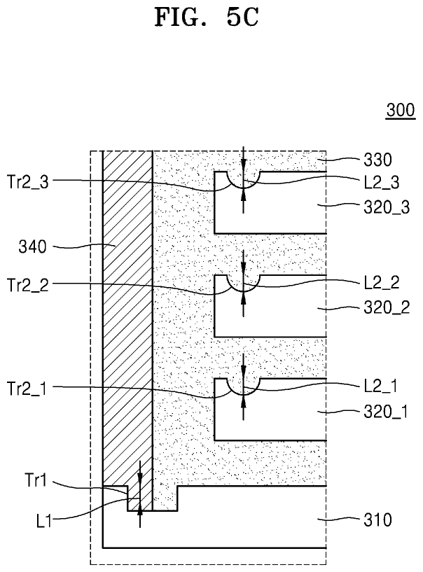

FIG. 5A is a plan view illustrating a semiconductor package 300 according to an embodiment. FIG. 5B is a cross-sectional view of the semiconductor package 300 taken along a line C-C′ of FIG. 5A. FIG. 5C is an enlarged cross-sectional of a region EX of FIG. 5B. Each configuration of the semiconductor package 300 shown in FIGS. 5A to 5C is similar to each configuration of the semiconductor package 100 described with reference to FIGS. 1A to 1C, and thus differences thereof are mainly described for economy of description.

Referring to FIGS. 5A to 5C, the semiconductor package 300 may include a lower chip 310, a chip stacked structure 320, an underfill layer 330, and a molding layer 340.

The lower chip 310 may include the plurality of through electrodes TSV, the plurality of lower pads Lp, and the plurality of upper pads Up.

The lower chip 310 may have the lower trench Tr1 positioned on an upper surface thereof. In an embodiment, the lower trench Tr1 may be a single trench having a serpentine shape in a plan view. For example, the lower trench Tr1 may be a single trench positioned on the upper surface of the lower chip 310 and having a serpentine shape extending along an edge of the upper surface of the lower chip 310.

In an embodiment, the lower trench Tr1 may have a quadrangular cross section. For example, the lower trench Tr1 may have a quadrangular shape in a cross section perpendicular to the second horizontal direction.

In an embodiment, the lower trench Tr1 may overlap the underfill layer 330 and the molding layer 340 in the vertical direction. For example, a boundary line where the underfill layer 330 and the molding layer 340 come into direct contact with each other may be positioned between both lateral side surfaces of the lower trench Tr1. Accordingly, based on the boundary line, an inner region of the lower trench Tr1 which is in direct contact with the underfill layer 330 in the vertical direction may be filled with the underfill layer 330, and an outer region of the lower trench Tr1 which is in direct contact with the molding layer 340 may be filled with the molding layer 340.

The plurality of first connection terminals SB1 may respectively disposed on the plurality of lower pads Lp of the lower chip 310.

The chip stacked structure 320 may be arranged on the lower chip 310. In an embodiment, the chip stacked structure 320 may include first to fourth upper chips 320_1, 320_2, 320_3, and 320_4, which are sequentially stacked (e.g., in the vertical direction). However, embodiments of the present disclosure are not necessarily limited thereto and the number of the upper chips of the chip stacked structure 320 may vary. Each of the first to third upper chips 320_1, 320_2, and 320_3 may include the plurality of through electrodes TSV, the plurality of lower pads Lp, and the plurality of upper pads Up. The fourth upper chip 320_4 may include only the plurality of lower pads Lp and may not include the plurality of through electrodes TSV and the plurality of upper pads Up.

The first to third upper chips 320_1, 320_2, and 320_3 may respectively have a plurality of first upper trenches to a plurality of third upper trenches Tr2_1, Tr2_2, and Tr2_3 positioned on upper surfaces thereof. For example, the first upper chip 320_1 may have the plurality of first upper trenches Tr2_1 positioned on the upper surface thereof, the second upper chip 320_2 may have the plurality of second upper trenches Tr2_2 positioned on the upper surface thereof, and the third upper chip 3203 may have the plurality of third upper trenches Tr2_3 positioned on the upper surface thereof. In an embodiment, some of the first to third upper trenches Tr2_1, Tr2_2, and Tr2_3 may be omitted. For example, in an embodiment the second upper trench Tr2_2 and the third upper trench Tr2_3 may be omitted, and only the plurality of first upper trenches Tr2_1 may be positioned on the upper surface of the first upper chip 320_1.

In an embodiment, the plurality of first upper trenches to the plurality of third upper trenches Tr2_1, Tr2_2, and Tr2_3 may each have a circular shape in a plan view and a semi-circular shape in a cross section. In an embodiment, the plurality of first upper trenches to the plurality of third upper trenches Tr2_1, Tr2_2, and Tr2_3 may respectively be arranged on the upper surfaces of the first to third upper chips 320_1, 320_2, and 320_3 to be spaced apart from each other along sides of the upper surfaces of the first to third upper chips 320_1, 320_2, and 320_3. For example, the plurality of second upper trenches Tr2_2 may be arranged on the upper surface of the second upper chip 320_2 to be spaced apart from each other along the edge of the upper surface of the second upper chip 320_2.

In an embodiment, each of the plurality of first upper trenches to the plurality of third upper trenches Tr2_1, Tr2_2, and Tr2_3 may overlap the underfill layer 330 in the vertical direction. Accordingly, each of the plurality of first upper trenches to the plurality of third upper trenches Tr2_1, Tr2_2, and Tr2_3 may be filled with the underfill layer 330.

The shape of the lower trench Tr1 and the shapes of the plurality of first upper trenches to the plurality of third upper trenches Tr2_1, Tr2_2, and Tr2_3 are not necessarily limited to those shown in FIGS. 5A to 5C. For example, unlike embodiments shown in FIGS. 5A to 5C, the lower trench Tr1 may include a plurality of trenches each having a circular shape in a plan view, and each of the first to third upper trenches Tr2_1, Tr2_2, and Tr2_3 may include a single trench having a serpentine shape in a plan view.

The plurality of second connection terminals SB2 may be disposed between the first to fourth upper chips 320_1, 320_2, 320_3, and 320_4 and between the first upper chip 320_1 and the lower chip 310. For example, the plurality of second connection terminals SB2 disposed between the first fourth upper chips 320_1, 320_2, 320_3, and 320_4 and between the first upper chip 320_1 and the lower chip 310 may have an upper surface directly contacting a lower pad Lp and a lower surface directly contacting an upper pad Up.

The underfill layer 330 may be between the first to fourth upper chips 320_1, 320_2, 320_3, and 320_4 and between the first upper chip 320_1 and the lower chip 310.

The molding layer 340 may be arranged on the lower chip 310 and may surround the chip stacked structure 320 and the underfill layer 330.

The semiconductor package 300 according to an embodiment may include the lower trench Tr1 positioned on the upper surface of the lower chip 310 and the first to third upper trenches Tr2_1, Tr2_2, and Tr2_3 respectively positioned on the upper surfaces of the first to third upper chips 320_1, 320_2, and 320_3. Due to the lower trench Tr1 and the first to third upper trenches Tr2_1, Tr2_2, and Tr2_3, thermo-mechanical stress applied to the upper surface of the lower chip 310 and the upper surface of each of the first to third upper chips 320_1, 320_2, and 320_3 may be reduced.

Also, the underfill layer 330 may fill the first to third upper trenches Tr2_1, Tr2_2, and Tr2_3, and the underfill layer 330 and the molding layer 340 may together fill the lower trench Tr1. Accordingly, an area in which each of the first to third upper chips 320_1, 320_2, and 320_3 directly contact the underfill layer 330 and an area in which the lower chip 310, the underfill layer 330, and the molding layer 340 directly contact each other may be increased. Accordingly, an adhesion strength between each of the first to third upper chips 320_1, 320_2, and 320_3 and the underfill layer 330 and an adhesion strength between the lower chip 310, the underfill layer 330, and the molding layer 340 may be increased.

FIG. 6 is a cross-sectional view illustrating a semiconductor package 1000 according to an embodiment.

Referring to FIG. 6, the semiconductor package 1000 may include the semiconductor package 100, a semiconductor chip 400, a molding layer 500, the redistribution structure 600, and a package substrate 700. FIG. 6 illustrates that the semiconductor package 1000 includes the semiconductor package 100 described with reference to FIGS. 1A to 1C. However, embodiments of the present disclosure are not necessarily limited thereto. For example, the semiconductor package 1000 may also include any one of the semiconductor packages 100a, 100b, 200, 200a, 200b, and 300 described with reference to FIGS. 2A to 5C.

FIG. 6 illustrates that the semiconductor package 1000 includes one semiconductor package 100. However, embodiments of the present disclosure are not necessarily limited thereto. For example, the semiconductor package 1000 may include one or more semiconductor packages 100. Also, the semiconductor package 1000 may include a plurality of semiconductor packages selected from among the semiconductor packages 100, 100a, 100b, 200, 200a, 200b, and 300 described with reference to FIGS. 1A to 5C. For example, in an embodiment in which the semiconductor package 1000 includes two semiconductor packages, a first semiconductor package may be the semiconductor package 100 described with reference to FIGS. 1A to 1C, and a second semiconductor package may be the semiconductor package 200 described with reference to FIGS. 3A to 3C.

In an embodiment, the package substrate 700 may be a printed circuit board. For example, the package substrate 700 may be a multi-layer printed circuit board. However, embodiments of the present disclosure are not necessarily limited thereto.

In an embodiment, the package substrate 700 may include a substrate base. The substrate base may include a single base layer or a structure in which a plurality of base layers are stacked. In an embodiment, the substrate base may include at least one material selected from a phenol resin, an epoxy resin, and polyimide. The substrate base may include, for example, at least one material selected from among frame retardant 4 (FR4), tetrafunctional epoxy, polyphenylene ether, epoxy/polyphenylene oxide, bismaleimide triazine (BT), thermount, cyanate ester, polyimide, and liquid crystal polymer. However, embodiments of the present disclosure are not necessarily limited thereto.

The redistribution structure 600 may be arranged on the package substrate 700. The redistribution structure 600 may be a substrate on which the semiconductor package 100 and the semiconductor chip 400 are mounted. In an embodiment, the redistribution structure 600 may be a redistribution interposer. In an embodiment, the redistribution structure 600 may include a redistribution insulating layer 610 and a redistribution pattern 620.

The redistribution insulating layer 610 may cover the redistribution pattern 620. The redistribution insulating layer 610 may include a plurality of insulating layers stacked in a vertical direction or may include a single insulating layer. In an embodiment, the redistribution insulating layer 610 may include, for example, a photo imageable dielectric (PID) or photosensitive polyimide (PSPI). However, embodiments of the present disclosure are not necessarily limited thereto.

The redistribution pattern 620 may include a plurality of redistribution lines 621 each extending in the first horizontal direction and a plurality of redistribution vias 623 extending at least partially through the redistribution insulating layer 610. The plurality of redistribution lines 621 may extend in a horizontal direction along at least one surface among upper and lower surfaces of each of insulating layers configuring the redistribution insulating layer 610. In an embodiment, at least some of the plurality of redistribution lines 621 may be positioned at a different vertical level from the remaining redistribution lines of the plurality of redistribution lines 621. The plurality of redistribution vias 623 may electrically connect the plurality of redistribution lines 621 located at different vertical levels to each other.

A first connection terminal SBP may be disposed between the package substrate 700 and the redistribution structure 600 (e.g., in the vertical direction). The first connection terminal SBP may physically and electrically connect the package substrate 700 and the redistribution structure 600 to each other. In an embodiment, the first connection terminal SBP may include, for example, solder.

The semiconductor chip 400 may be arranged on the redistribution structure 600. In an embodiment, the semiconductor chip 400 may be a memory chip or a logic chip. The memory chip may include, for example, a volatile memory chip such as a DRAM or SRAM chip, or a non-volatile memory chip such as a PRAM, MRAM, FeRAM, or RRAM chip. Also, the logic chip may include, for example, a microprocessor, an analog device, or a digital signal processor. However, embodiments of the present disclosure are not necessarily limited thereto.

The semiconductor chip 400 may include a semiconductor substrate 410 and a chip pad 420. The semiconductor substrate 410 may include a semiconductor material. The semiconductor substrate 410 may include a conductive region, for example, a well doped with impurities. The semiconductor substrate 410 may have various device isolation structures, such as an STI structure.

A second connection terminal BP may be disposed between the semiconductor chip 400 and the redistribution structure 600. The second connection terminal BP may be in direct contact with the chip pad 420 of the semiconductor chip 400 and the redistribution structure 600 and may physically and electrically connect the semiconductor chip 400 and the redistribution structure 600 to each other. In an embodiment, the second connection terminal BP may include a material substantially the same as or similar to that of the first connection terminal SBP.

The molding layer 500 may be arranged on the redistribution structure 600 and may cover at least a portion of the semiconductor chip 400 and at least a portion of the semiconductor package 100. The molding layer 500 may include a material substantially the same as or similar to that of the molding layer 140 described with reference to FIGS. 1A to 1C.

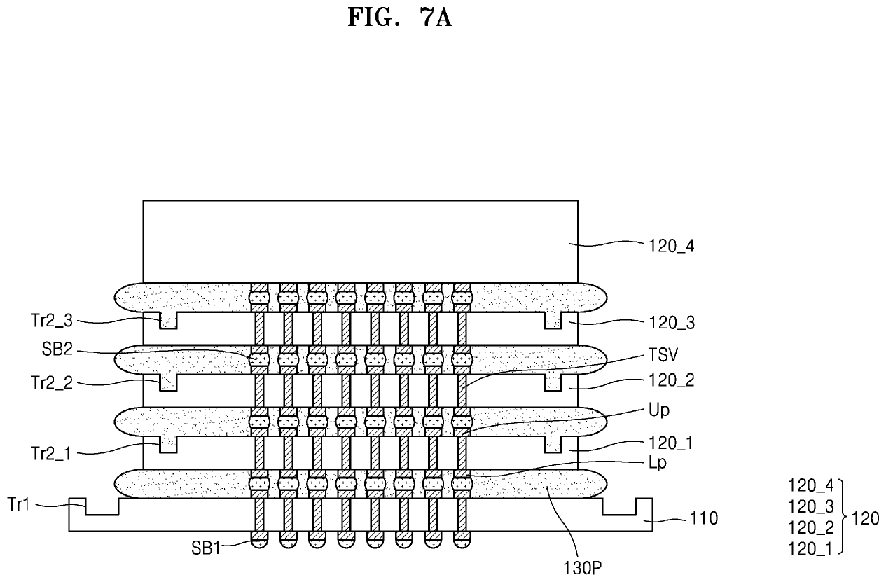

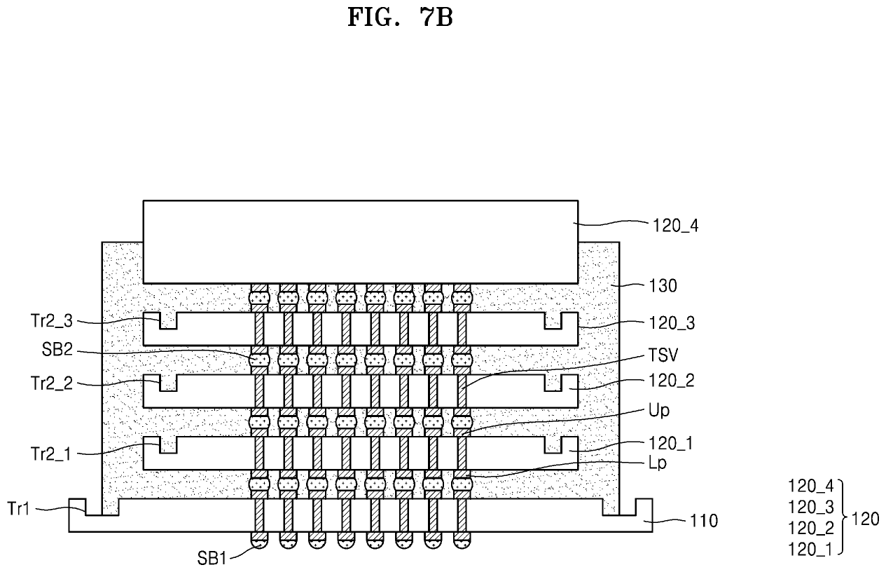

FIGS. 7A and 7B are cross-sectional views illustrating a method of manufacturing the semiconductor package 100 according to embodiments of the present disclosure.

Referring to FIG. 7A, firstly, the lower chip 110 having the lower trench Tr1 positioned on the upper surface thereof may be provided. The chip stacked structure 120 including the first to third upper chips 120_1, 120_2, 120_3 respectively having first to third upper trenches Tr2_1, Tr2_2, and Tr2_3 on upper surfaces thereof and the fourth upper chip 120_4 may then be mounted on the lower chip 110. An underfill process may then be performed, and an underfill material layer 130P may be filled between the lower chip 110 and the first upper chip 120_1 and between the first to fourth upper chips 120_1, 120_2, 120_3, and 120_4. In a process in which the underfill material layer 130P is filled, the first to third upper trenches Tr2_1, Tr2_2, and Tr2_3 may be filled with the underfill material layer 130P.

Referring to FIG. 7B, a thermal bonding process may be performed on a resultant product of FIG. 7A. Accordingly, the underfill layer 130 may be formed by melting underfill material layers 130P of FIG. 7A into one body. In a process in which the underfill layer 130 is formed, a partial region of the lower trench Tr1 may be filled with the underfill layer 130.

The molding layer 140 may then be formed in a resultant product of FIG. 7B. In an embodiment, a remaining region of the lower trench Tr1 may be filled with the molding layer 140. The semiconductor package 100 shown in FIGS. 1A to 1C may be manufactured by forming the molding layer 140 on the lower chip 110 to surround the underfill layer 130 and the chip stacked structure 120.

While the present disclosure has been particularly shown and described with reference to non-limiting embodiments thereof, it will be understood that various changes in form and details may be made therein without departing from the spirit and scope of the present disclosure.

What is claimed is:

1. A semiconductor package comprising:
a lower chip;
a chip stacked structure arranged on the lower chip, the chip stacked structure comprising a plurality of upper chips;
an underfill layer disposed between the lower chip and the chip stacked structure and between the plurality of upper chips; and
a molding layer surrounding the underfill layer and the chip stacked structure,
wherein the lower chip has at least one lower trench positioned on an upper surface of the lower chip, and
at least one of the plurality of upper chips has at least one upper trench positioned on an upper surface of the at least one of the plurality of upper chips.

2. The semiconductor package of claim 1, wherein:
a portion of the at least one lower trench overlaps the molding layer in a vertical direction, and a remaining portion of the at least one lower trench overlaps the underfill layer in the vertical direction,
the portion of the at least one lower trench overlapping the molding layer in the vertical direction is filled with the molding layer; and
the remaining portion of the at least one lower trench overlapping the underfill layer in the vertical direction is filled with the underfill layer.

3. The semiconductor package of claim 1, wherein:
the at least one upper trench overlaps the underfill layer in a vertical direction; and
the at least one upper trench is filled with the underfill layer.

4. The semiconductor package of claim 1, wherein each of the plurality of upper chips except for an uppermost chip of the plurality of upper chips includes the at least one upper trench.

5. The semiconductor package of claim 4, wherein the at least one upper trenches of the plurality of upper chips overlap each other in a vertical direction.

6. The semiconductor package of claim 1, wherein at least one of the at least one lower trench and the at least one upper trench has a serpentine shape extending along an edge of the upper surface of the lower chip or an upper chip of the plurality of upper chips, respectively, in a plan view.

7. The semiconductor package of claim 1, wherein at least one of a cross section of the at least one lower trench and a cross section of the at least one upper trench has a shape selected from a quadrangular shape, a triangular shape, and a U shape.

8. The semiconductor package of claim 1, wherein at least one of the at least one lower trench and the at least one upper trench comprises a plurality of trenches each having a circular shape in a plan view, the plurality of trenches are arranged along an edge of the upper surface of the lower chip and an upper chip of the plurality of upper chips, respectively, to be spaced apart from each other.

9. The semiconductor package of claim 1, wherein the at least one upper trench and the at least one lower trench have different shapes from each other in a plan view.

10. The semiconductor package of claim 1, wherein:
each of the lower chip and the chip stacked structure configures highband memory (HBM); and
each of the plurality of upper chips of the chip stacked structure comprises dynamic random access memory (DRAM).

11. The semiconductor package of claim 1, wherein the lower chip and at least some of the plurality of upper chips comprise through electrodes penetrating the lower chip and the at least some of the plurality of upper chips, respectively, in a vertical direction.

12. A semiconductor package comprising:
a lower chip;
a chip stacked structure arranged on the lower chip, the chip stacked structure comprising a plurality of upper chips;
an underfill layer disposed between the lower chip and the chip stacked structure and between the plurality of upper chips; and
a molding layer surrounding the underfill layer and the chip stacked structure,
wherein the lower chip has at least one lower trench positioned on an upper surface of the lower chip,
a portion of the at least one lower trench overlaps the molding layer in a vertical direction, and a remaining portion of the at least one lower trench overlaps the underfill layer in the vertical direction, and
the portion of the at least one lower trench overlapping the molding layer in the vertical direction is filled with the molding layer, and the remaining portion of the at least one lower trench overlapping the underfill layer in the vertical direction is filled with the underfill layer.

13. The semiconductor package of claim 12, wherein the at least one lower trench comprises a single trench having a serpentine shape extending along an edge of the upper surface of the lower chip in a plan view.

14. The semiconductor package of claim 12, wherein a cross section of the at least one lower trench has a shape selected from a quadrangular shape, a triangular shape, and a U shape.

15. The semiconductor package of claim 12, wherein:
the at least one lower trench comprises a plurality of trenches arranged along an edge of the upper surface of the lower chip to be spaced apart from each other; and
each of the plurality of trenches has a circular shape in a plan view.

16. The semiconductor package of claim 15, wherein a plurality of lower trenches are arranged in two rows along the edge of the upper surface of the lower chip in a plan view.

17. The semiconductor package of claim 16, wherein:
among the plurality of lower trenches, a first lower trench is arranged adjacent to the edge of the upper surface of the lower chip and overlaps the molding layer and the underfill layer in a vertical direction;
among the plurality of lower trenches, a second lower trench is arranged farther from the edge of the upper surface of the lower chip than the first lower trench, the second lower trench solely overlaps the underfill layer in the vertical direction; and
each of the lower chip and the chip stacked structure configures highband memory (HBM), and each of the plurality of upper chips of the chip stacked structure comprises dynamic random access memory (DRAM).

18. The semiconductor package of claim 16, wherein a vertical length of the at least one lower trench is in a range of about 1 μm to about 500 μm.

19. A semiconductor package comprising:
a package substrate;
a redistribution structure arranged on the package substrate;
a sub-semiconductor package arranged on the redistribution structure; and
a semiconductor chip arranged on the redistribution structure and spaced apart from the sub-semiconductor package in a horizontal direction,
wherein the sub-semiconductor package comprises a lower chip, a chip stacked structure arranged on the lower chip, the chip stacked structure comprising a plurality of upper chips, an underfill layer disposed between the lower chip and the chip stacked structure and between the plurality of upper chips, and a molding layer surrounding the underfill layer and the chip stacked structure,
wherein the lower chip has at least one lower trench positioned on an upper surface of the lower chip, and at least one of the plurality of upper chips has at least one upper trench positioned on an upper surface of the at least one of the plurality of upper chips.

20. The semiconductor package of claim 19, wherein:
a portion of the at least one lower trench overlaps the molding layer in a vertical direction, and a remaining portion of the at least one lower trench overlaps the underfill layer in the vertical direction;
the portion of the at least one lower trench overlapping the molding layer in the vertical direction is filled with the molding layer, and the remaining portion of the at least one lower trench overlapping the underfill layer in the vertical direction is filled with the underfill layer; and
each of the lower chip and the chip stacked structure configures highband memory (HBM), and each of the plurality of upper chips of the chip stacked structure comprises dynamic random access memory (DRAM).
